(19) United States
(12) Patent Application Publication
(10) Pub. No.: US 2007/0037363 A1
(43) Pub. Date: Feb. 15, 2007

(54) Method for forming a brittle zone in a substrate by co-implantation

(76) Inventors: Bernard Aspar, Rivers (FR); Christelle Lagahe, Saint Joseph de Riviere (FR); Nicolas Sousbie, Grenoble (FR); Jean-Francois Michaud, Saint Pierre de Soucy (FR)

Correspondence Address: BRINKS HOFER GILSON & LIONE, P.O. BOX 10395, CHICAGO, IL, 60610, US

(21) Appl. No.: 10/534,199

(22) PCT Filed: May 27, 2004
(86) PCT No.: PCT/FR03/03256

§ 371 Date: Oct. 16, 2006

(30) Foreign Application Priority Data
Nov. 7, 2002 (FR) 02/13934

(51) Int. Cl. H01L 21/30; H01L 21/46

(52) U.S. Cl. 438/459

(57) ABSTRACT

The invention concerns a method for making a thin film, which consists in creating a brittle zone embedded by implantation of a chemical species in a substrate, so as to be able subsequently to provoke a fracture of the substrate along said brittle zone to separate therefrom said thin film. The invention is characterized in that the manufacturing method comprises in particular the following steps: a) a first implantation in the substrate at a first depth of a first chemical species; b) implanting at least one second chemical species in the substrate, at a second depth different from said first depth, and at a concentration higher than the concentration of the first species, where the at least a second chemical species is less efficient than the first chemical species for embrittling the substrate; c) diffusing at least part of said secondary species to the vicinity of the first depth; and d) initiating a fracture along the first depth. The invention also concerns the thin film obtained by the inventive method.

The invention relates to separating a thin layer at the surface of a “source” substrate, usually to transfer the thin layer onto a “target” substrate.

By “thin layer” is meant, conventionally, a layer whose thickness is usually from a few tens of angstrom units to several micrometers.

There are many examples of applications in which layer transfer techniques represent a solution to the problem of integrating layers onto a support that is a priori unsuitable for producing them. The transfer of a thin layer onto another support gives engineers a valuable option to design structures that are otherwise impossible.

For example, these removals of thin films can produce “buried” structures, such as buried capacitors for dynamic random access memories (DRAM), where the capacitors are fabricated and then transferred onto another silicon substrate; the remainder of the circuits are then fabricated on the new substrate.

Another example is encountered in the field of applications relating to telecommunications and microwaves. In this case, it is preferable for the microcomponents to be integrated at the final stage onto a support having a high resistivity, typically at least several kohm·cm. However, it is not easy to obtain a highly resistive substrate at the same cost and of the same quality as the standard substrates usually employed. One solution consists in producing the microcomponents on standard substrates and then, during the final steps, transferring a thin layer containing the microcomponents onto an insulative substrate such as glass, quartz or sapphire.

From a technical point of view, these transfer operations have the major benefit of decorrelating the properties of the layer in which the microcomponents are fabricated from those of the layer serving as the final support, and are therefore of benefit in many other situations.

There may also be mentioned cases in which the substrate that is beneficial for the fabrication of the microcomponents is excessively costly. In this case, for example that of silicon carbide, which offers better performance (higher temperatures of use, significantly improved maximum powers and frequencies of use, and so on), but the cost of which is very high compared to silicon, it would be beneficial to transfer a thin layer of the costly substrate (here silicon carbide) onto the inexpensive substrate (here silicon), and to recover the remainder of the costly substrate for reuse, possibly after a recycling operation. The transfer operation can take place before, during, or after the fabrication of the microcomponents.

The above techniques can also be of benefit in all fields in which obtaining a thin substrate is important for the final application. Power applications in particular may be cited, for reasons associated with the evacuation of heat (which is improved if the substrate is thin), or because the electrical current must sometimes flow through the thickness of the substrate, with losses that are to a first approximation proportional to the thickness through which the current flows. Smart card applications may also be cited, in which thin substrates are required for reasons of flexibility. Likewise, applications intended to produce three-dimensional circuits and stacked structures may be cited.

For many applications the preliminary steps are carried out on thick substrates or substrates of standard thickness, with the advantages, firstly, of mechanical ruggedness to withstand the various technology steps, and, secondly, of conforming to standards relating to their processing on certain types of production equipment. It is therefore necessary to carry out a thinning process that leads to the final application.

Some prior art methods for transferring a thin layer from a source substrate onto a target substrate are based on creating a weak buried layer in a material by implanting one or more gaseous species.

Patent application FR-2 681 472 discloses one such process. The species implanted create a buried region that is weakened by the presence of defects such as microcavities, in particular microbubbles (which are essentially spherical in shape) or platelets (which are substantially lens-shaped). The buried region and the surface of the source substrate together delimit a thin layer that is subsequently transferred onto the target substrate.

For other ways of creating a buried layer weakened by implanting one or more gaseous species, see also the documents U.S. Pat. No. 5,374,564 (or EP-A-53351), U.S. Pat. No. 6,020,252 (or EP-A-807970), FR-2 767 416 (or EP-A-1010198), FR-2 748 850 (or EP-A-902843), FR-2 748 851 and FR-2 773 261 (or EP-A-963598).

The characteristic size of the defects created by ion implantation runs from one nanometer to a few tens of nanometers. The substrate weakened in this way can if necessary undergo heat treatment: steps are then taken to prevent thermal annealing inducing surface exfoliation or deformation. The weakened substrate can also undergo deposition, thermal oxidation, or gas or liquid phase epitaxy steps, or processes that produce electronic and/or optical microcomponents and/or sensors.

If the implantation levels are chosen correctly, subsequent input of energy to the buried weakened region, for example by heat treatment, encourages the growth of microcavities, forming microcracks. The buried layer of inclusions is used as a trapping layer in the substrate. This localizes, preferably in the trapping layer, and in sufficient quantities, gaseous species that can contribute to the final separation of the thin surface layer delimited by the region of inclusions and the surface of the source substrate.

This separation step can be effected using appropriate heat and/or mechanical treatments.

The advantage of the above weak buried layer processes is that they can produce very homogeneous layers based on crystalline materials (Si, SiC, InP, AsGa, LiNbO₃, LiTaO₃, etc.) in a range of thicknesses from a few tens of angstrom units to several micrometers. Greater thicknesses are also accessible.

The above methods in particular allow reuse of the substrate after separation, very little of such substrates being consumed on each cycle. The substrates are, indeed, usually several hundred microns thick. Thus the substrates used can be described as “recyclable” substrates.

The gaseous species implanted in the source substrate can be ions of hydrogen and/or rare gases, for example.

The paper “Efficient production of silicon-on-insulator films by co-implantation of He⁺ with H⁺” by Agarwal et al. (Appl. Phys. Lett., Vol. 72, No 9, March 1998) describes a method comprising the co-implantation in a silicon substrate of two chemical species, namely hydrogen and helium. The authors specify that the implantation profiles of the two implanted species must be localized to the same depth. It is thus possible to reduce the total dose implanted and enabling subsequent fracture, compared to using either of the two chemical species alone: according to the authors, this technique reduces the total dose implanted by an amount of the order of 50%. The authors also disclose that the order in which the two implanted species are implanted is important: the hydrogen must be implanted first, and the helium second; they assert that if the helium were implanted first the reduction in the total dose implanted would be less.

When atoms are caused to penetrate into the source substrate, for example by ion implantation, those atoms are distributed in accordance with a quasi-Gaussian profile that features a peak and has a maximum concentration at a certain depth, which depth increases with the atom implantation energy. From a concentration that is referred to herein as the “critical” concentration, the implanted atoms generate defects in the material that degrade the crystal quality of the material, as explained hereinabove, for example defects in the form of microbubbles and/or platelets and/or microcavities and/or dislocation loops and/or other crystal defects. The critical concentration depends greatly on the species implanted and on the nature of the source substrate in which it is implanted.

The subsequent fracture of the substrate shall occur at depths at which the density of crystal defects is sufficiently high, which requires that the implanted concentration exceed the critical concentration by a sufficient amount. The depth of the implantation peak being a function of the ion implantation energy, it is that energy which in the final analysis determines the thickness of the thin layer to be transferred.

After fracture, the transferred thin layer has a disturbed layer on the surface: in the context of the present invention, the expression “disturbed layer” refers to a layer including vestiges of the destructive effects of ion implantation, in the form of roughness and crystal defects. The thickness of the disturbed layer increases with the implantation energy and with the implanted ion concentration.

To obtain a transferred thin layer of excellent quality, it is necessary to eliminate the disturbed layer. There are many techniques for this elimination: for example, chemical-mechanical polishing, sacrificial oxidation, and (wet or dry) chemical etching may be cited. Note that the greater the thickness removed, the greater the risk of degrading the homogeneity of the thickness of the transferred thin layer. Reducing the thickness of the disturbed layer limits the extent of the processing cited above and therefore has the particular advantage of encouraging in its thickness a homogeneous transferred thin layer. In some applications, reducing the costs of processing the substrates after transfer is also a major benefit.

Patent application WO 99/39378 discloses a method of reducing the thickness of the disturbed layer present on the surface of the transferred thin layer after the fracture step. The document proposes multiple implantations in the source substrate. The steps consist in:
implanting atoms in the source substrate at a first depth to obtain a first concentration of atoms at that first depth,
implanting atoms in the same substrate at a second depth, different from the first, to obtain at the second depth a second concentration of atoms lower than the first, and
applying to the substrate processing adapted to cause at least some of the atoms implanted at the second depth to migrate toward the first depth, in such a manner as to preferably generate microcavities at the first depth.

The general principle of this invention lies in a sequence of two or more implantation steps at two or more different depths. The expression “main peak” is used hereinafter to designate the implanted species peak at which the fracture is to be effected subsequently, and the expression “secondary peak” is used hereinafter to designate all other implanted species.

A disadvantage of the above process is that the concentrations of implanted ions in the secondary peak(s) (which form reservoirs of atoms for the first peak), are kept below the concentration at the main peak.

Consequently, if it is required to reduce significantly the concentration of ions implanted at said first depth (in order to reduce the thickness of the disturbed region after fracture), it becomes necessary to carry out a large number of successive implantations, so as to introduce into the source substrate the necessary quantity of atoms for subsequently obtaining the fracture at the level of the first peak. Carrying out a large number of implantations increases the cost of the process and makes the chaining of the steps particularly complex.

To remedy this drawback, in a first aspect, the invention proposes a method of fabricating a thin layer, in which a weak buried region is created by implanting a chemical species in a substrate in order thereafter to be able to initiate a fracture of said substrate along said weak region in order to detach said thin layer therefrom, said method being noteworthy in that it includes the following steps:

a) a “main” implantation of a “main” chemical species in the substrate at a “main” depth, and

b) at least one “secondary” implantation of at least one “secondary” chemical species less effective than the main species at weakening the substrate, in the substrate at a “secondary” depth different from said main depth and at a concentration higher than the concentration of the main species,

wherein said steps a) and b) can be executed in either order, and in that it further includes the following steps:

c) migration of at least a portion of said secondary species up to the neighborhood of the main depth, and

d) initiation of said fracture along the main depth.

Thus, in accordance with the invention, at least two different species are implanted, characterized by their different effectiveness at forming a weakened region in the source substrate. By weakening is meant the formation of specific defects of the microbubble and/or microcavity and/or platelet and/or other crystal defect types whose shape, size, and density are propitious to the future propagation of a fracture in that region. The effectiveness of a given chemical species at forming a weakened region is greatly dependent on the material constituting the substrate. For example, the main chemical species implanted can consist of hydrogen ions, the secondary chemical species(s) implanted can consist of ions of at least one rare gas, and the substrate can be of silicon, although this combination is not limiting.

One of the implanted profiles localizes the fracture that will subsequently be initiated and shall enable the transfer of a thin surface layer; the other implanted profile corresponds to a reservoir of species which, after migration, facilitate the propagation of the fracture. Two implantations are usually sufficient.

It shall be noted that the secondary concentration of the less effective species can be equal to a large fraction of the concentration that would be sufficient for the substrate to fracture subsequently at the level of the secondary implantation (when choosing this secondary concentration, it is naturally necessary to retain a certain safety margin to prevent the substrate fracturing at this level). Since, in accordance with the invention, the secondary species is less effective than the main species, it means in practice that the secondary concentration can be much higher than the main concentration.

Thus, according to the present invention, a weakened region adapted to serve subsequently as a fracture line and in which the disturbed layer is also relatively thin is obtained by means of a small number of implantations.

Without claiming to provide a definitive physical explanation, these advantages of the invention may be attributed to the following mechanism. In considering this mechanism, it must be borne in mind that, after implantation, the implanted ions may possibly form neutral atoms or be bonded to the substrate.

It is probable that the “effectiveness” of a species, that is to say its capacity to weaken the substrate, goes hand in hand with the previously mentioned trapping of the implanted species in the defects generated by implantation. For example, in the case of implanting H⁺ ions in silicon, it is known that these two effects probably result from the capacity of this species to form chemical bonds with the substrate. Accordingly, during step c), the tendency to diffuse away from its implantation peak is stronger for the secondary species than for the main species, precisely because the secondary species is less effective than the main species. The secondary species, in the form of concentrated free gas, is then accommodated in the microcavities previously created by the main implantation, and encourages the growth of the microcavities, without at the same time increasing the size of the disturbed region at the level of the main peak.

According to particular features, said secondary depth is greater than said main depth. In this case, any crystal defects generated by the secondary implantation are situated outside the thin layer obtained by the method according to the invention. This arrangement therefore contributes to obtaining a thin layer of high quality.

According to other particular features, the secondary depth is, to the contrary, less than the main depth. This can be advantageous in some applications, for example when the secondary implantation is required to form a layer of specific crystal defects localized to the thin layer; this layer of defects can have electrical insulation and/or trapping properties, for example.

According to particular features, said step c) of migration is encouraged by appropriate heat treatment. This feature considerably increases the effectiveness of the method according to the invention, and also reduces its implementation time. This is because this kind of heat treatment has a two-fold role: firstly, it encourages the growth of the crystal defects present at the level of the main peak and, secondly, it simultaneously encourages the migration of the secondary species (ions or atoms).

According to other particular features, said step d) is carried out by appropriate heat treatment. Because of this heat treatment, the secondary species gas creates a major pressure effect at the level of the main implantation peak that contributes to fracturing the source substrate.

The characteristics of the heat treatments applied are chosen carefully as a function of the application concerned. For example, for some applications, it may be beneficial—and, thanks to the invention, possible—to operate with a thermal budget lower than that which would be necessary to initiate said fracture in the absence of steps b) and c), i.e. in accordance with the prior art (the expression “thermal budget” means the application of a given temperature for a given time). From another point of view, given a predetermined thermal budget (required by a particular application of the invention), care is taken to conform to the thermal budget, if necessary by implanting more of a secondary species than would be necessary to initiate said fracture within a thermal budget higher than said predetermined thermal budget.

In a second aspect, the invention relates to a thin layer obtained by one of the methods briefly described hereinabove, before or after its transfer onto a final support.

Other aspects and advantages of the invention will become apparent on reading the following detailed description of particular embodiments of the invention provided by way of nonlimiting examples. The description refers to the appended drawings, in which:

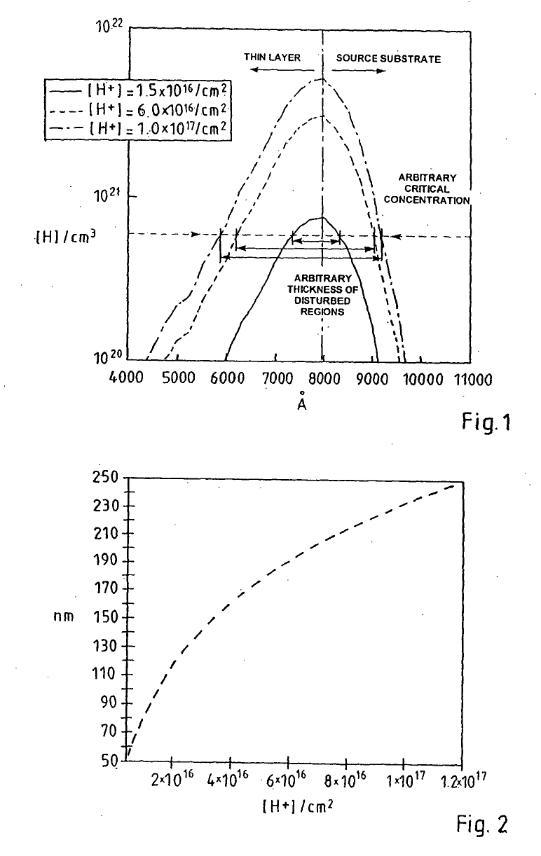

FIG. 1 is a graph showing the concentration profiles of hydrogen ions or atoms implanted in a substrate as a function of the depth in the substrate, for three implantation doses indicated by way of example,

FIG. 2 is a graph showing the thickness of the disturbed region as a function of the implantation dose in the case of implanting H⁺ ions in silicon,

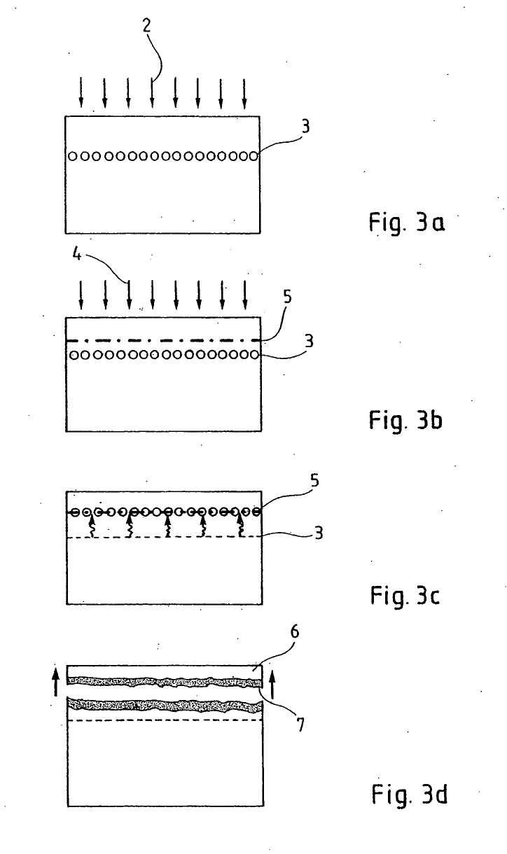

FIGS. 3a to 3d show the successive main steps of the method according to the invention, and

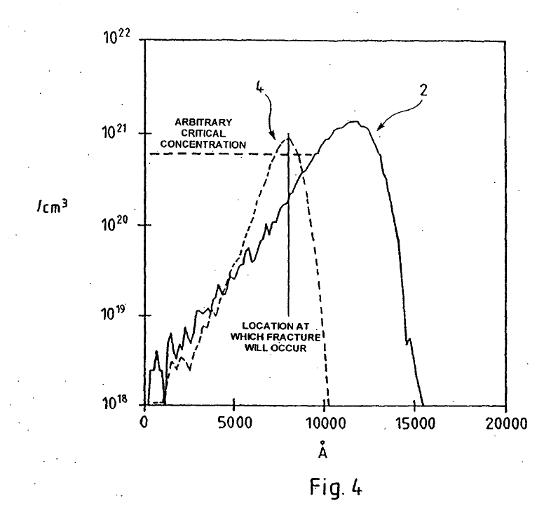

FIG. 4 is a graph showing the concentration profiles, as a function of the depth in the substrate, of the main species and the secondary species implanted during the steps shown in FIGS. 3a and 3b.

FIG. 1 shows, by way of example, three implantation profiles of H⁺ ions in a silicon substrate. The profiles show the concentration (expressed as a number of hydrogen ions or atoms per cm³) obtained in the substrate as a function of the depth below the implanted surface of the substrate, at ion implantation doses of 1.5×10¹⁶ H⁺/cm², 6.0×10¹⁶H⁺/cm², and 1.0×10¹⁷ H⁺/cm², and at an energy of approximately 75 keV. The figure indicates, purely by way of illustration, the minimum concentration level (critical concentration) that leads to the appearance of crystal defects caused by ion implantation.

Here, the three concentration curves rise above the critical concentration, such that the existence of a disturbed region in the substrate (a region including crystal defects caused by ion implantation) and essentially situated between the two depths at which said curve crosses the critical concentration line can be deduced therefrom for each concentration curve.

A corresponding thickness of the disturbed region can therefore be associated with each implantation of sufficiently high dose, as shown by way of illustration only in FIG. 1. FIG. 2 sets out experimental data relating to this thickness, for a range of implantation doses from 0.5×10¹⁶ H⁺/cm² to 1.2×10¹⁷ H⁺/cm² and at an energy of approximately 75 keV. Note that the width of the disturbed region increases with the implanted dose, here from 50 to 250 nanometers (nm) approximately. After fracture, the thickness of the disturbed layer showing on the surface of the transferred thin layer is approximately ⅓ to ⅔ the thickness of the disturbed region before fracture.

FIGS. 3a to 3d show the successive main steps of a method according to an embodiment of the invention.

FIG. 3a shows the implantation of a source substrate 1 with a “secondary” chemical species 2, which creates a concentration of the secondary species 2 within the substrate 1 about a “secondary” depth peak 3.

FIG. 3b shows implantation with a “main” chemical species 4 from above the same portion of the substrate 1, which creates a concentration of the main species 4 within the substrate 1 about a “main” depth peak 5.

The method according to the invention teaches implanting a species 4 that is highly effective in weakening the source substrate at the level of the main peak 5. Species 2 that are less effective at forming weakening defects are implanted at the level of the secondary peak 3.

The embodiment shown here relates to an application in which it is important to optimize the quality of the thin layer obtained at the end of the process. This is why the implantation of the secondary species 2, which serves to constitute a reservoir of atoms, is carried out here at a depth 3 greater than the implantation depth 5 of the main species 4, at which the substrate 1 subsequently fractures.

FIG. 3c shows the next step of this embodiment of the invention. During this step, heat treatment is preferably applied (furnace and/or local heating and/or a laser beam, or otherwise), as explained in the introduction. A large fraction of these species then feeds the crystal defects at the level of the main peak (5) and encourage the growth of these defects.

Finally, FIG. 3d shows the conventional operation of fracturing the substrate 1 at the main depth 5 in order to detach from the source substrate 1 a thin layer 6 that can where appropriate be transferred onto a target substrate (not shown). Detachment exposes a fine disturbed layer 7 on the surface of the thin layer 6 (and another disturbed layer on the surface of the source substrate 1).

Fracture can optionally, in a known way, be initiated by applying heat treatment (furnace and/or local heating and/or a laser beam, or otherwise) and/or by applying mechanical stresses, such as spraying a jet of fluid (gas, liquid) and/or inserting a blade into the weakened region, and/or by applying traction, shear or bending stresses to the substrate and/or acoustic waves (ultrasound or otherwise).

If the choice is made to use heat treatment during the migration step c), it is advantageous, for reasons of simplicity of implementation, to use the same heat treatment for step d). The two steps c) and d) can then conveniently be carried out without interruption.

According to a variant, a layer of a thickener such as an oxide or a nitride or any other, in a known way, is applied first; the presence of this support stiffens the layer transferred from the weakened substrate, in particular for transport and/or finishing steps; the propagation of the fracture at the level of the main peak therefore yields a self-supporting layer comprising the thin layer from the source substrate and the layer of thickener.

Another variant is bonding the implanted source substrate to a target substrate. For example, the target substrate can be of silicon, a plastics material, or glass, and can be flexible or rigid. The attachment can be effected by direct bonding (molecular adhesion), for example, or by using glues or other adhesives; the macroscopic fracture along the weakened region then causes separation of the bonded structure consisting of the source and target substrates into two portions: a first portion consisting of the thin surface layer from the source substrate, transferred onto the target substrate, and a second portion consisting of the source substrate from which a thin surface layer has been peeled.

Yet another variant is, before or during step d), applying a “handle” support to the substrate 1, after which the thin layer 6 is transferred onto a final support.

After separation and transfer of the thin surface layer, the remainder of the weakened substrate can be recycled either as a source substrate or, where appropriate, as a target substrate.

The advantage of the method according to the invention over the technique described in the document WO 99/39378 is that, because of the different properties of the two species implanted at the level of the main and secondary peaks, the dose implanted at the level of the main peak can be enormously reduced compared to the usual dose necessary in the case of a single implantation (for example in the case of implanting only hydrogen ions in silicon, the usual dose is from 5×10¹⁶ to 10¹⁷ H⁺/cm²). The present inventors have measured a reduction in the main species dose as high as 80%. In parallel with this, the concentration of the species 2 implanted at the level of the secondary peak 3 can significantly exceed the concentration of the species 4 implanted at the level of the main peak 5, as can be seen in FIG. 4. Thus the secondary peak 3 serves as a reservoir of secondary species 2 intended to migrate toward the main peak 5.

The present invention is suited in particular to applications requiring a low thermal budget. For example, if it is required to transfer and bond a thin layer of a material A onto a substrate of a material B and the mechanical properties of the two materials are different (for example their coefficients of thermal expansion), the heat treatments applied may not exceed a particular thermal budget above which the bonded structure consisting of the two substrates of the materials A and B may suffer damage (such as breaking and/or unsticking).

For applications of this kind, the method according to the invention can be implemented by choosing the implanted doses of the two species so as simultaneously to initiate a fracture at a low temperature at a predetermined depth and to impose a predetermined thickness of the disturbed area. The dose of secondary species 2 is then increased relative to the dose according to the invention, to encourage the fracture kinetics; moreover, the dose of the species 4 implanted at the level of the main peak can lie between the dose according to the invention and the usual dose necessary for localizing the fracture. Thanks to these features, a fracture at a low temperature can be obtained in a reasonable time, whilst retaining the advantages resulting from the fact that the disturbed area observed after fracture is thin.

To complete the description, there follow three numerical examples of implementation of the invention.

In a first example, a substrate of silicon (Si) having a 50 nm thick, for example, layer of thermal silica (SiO₂) on the surface is implanted with neon atoms at the rate of 2×10¹⁶ Ne/cm² and at an energy of 210 keV, and is then implanted with hydrogen at the rate of 7×10¹⁵ H⁺/cm² and at an energy of 20 keV. This source substrate is then attached to a target Si substrate by direct bonding. Heat treatment at 500° C. then induces the growth of microcavities and/or platelets localized to the level of the hydrogen peak: the neon atoms migrate to the hydrogen peak and participate in the growth of crystal defects that lead to the final fracture. Thanks to the invention, the width of the disturbed region is no more than approximately 70 nm, whereas in the case of a single implantation in accordance with the prior art (at a rate of the order of 5×10¹⁶ H⁺/cm²), the width of the disturbed region is approximately 150 nm.

In a second example, a substrate of germanium (Ge) onto which a 100 nm thick, for example, layer of SiO₂ has been deposited is implanted with helium atoms at the rate of 4×10¹⁶ H⁺/cm² and at an energy of 180 keV, and is then implanted with hydrogen at the rate of 2×10¹⁶ H⁺/cm² and at an energy of 60 keV. This source substrate can then be attached to a target Si substrate by direct bonding. Heat treatment at 300° C. then induces the growth of microcavities and/or platelets localized to the level of the hydrogen peak, the helium atoms diffusing as far as this region of crystal defects and participating in their pressurization and development. The final fracture at the level of the hydrogen profile leads to the transfer of the layer of Ge onto the Si substrate. Thanks to the invention, the width of the disturbed region is only about 300 nm, whereas in the case of a single implantation in accordance with the prior art the width of the disturbed region is approximately 400 nm.

In a third example, an Si substrate having a 200 nm thick, for example, layer of thermal SiO₂ on the surface is implanted with helium atoms at the rate of 4×10¹⁶ H⁺/cm² and at an energy of 180 keV and is then implanted with hydrogen at the rate of 2×10¹⁶ H⁺/cm² and at an energy of 75 keV. This source substrate can then be attached to a fused silica target substrate by direct bonding. The difference between the coefficients of thermal expansion of the two materials imposes the application of heat treatment to enable fracture at a low temperature, usually of the order of 300° C. With the hydrogen only implantation doses conventionally used (which are of the order of 9×10¹⁶ H⁺/cm²), several days would be required to be able to initiate fracture of the Si substrate along the weak region at this temperature. In contrast, with the above co-implantation conditions, heat treatment induces the growth of cavities localized at the level of the hydrogen peak, the helium atoms diffusing as far as the region of crystal defects and participating in their pressurization and development, so that the final fracture at the level of the hydrogen profile can be achieved in only about an hour. Thus the Si layer is transferred efficiently onto the fused silica substrate. Moreover, thanks to the invention, the width of the disturbed region is only about 110 nm, whereas in the case of single implantation according to the prior art, the width of the disturbed region is approximately 230 nm.

1. A method of fabricating a thin layer, in which a weak buried region is created by implanting a chemical species in a substrate in order to thereafter initiate a fracture of said substrate along said weak region to detach said thin layer therefrom, said method comprising:
a) implanting a first chemical species in the substrate at a first depth;
b) implanting at least one second chemical species, in the substrate at a second-depth different from said first depth and at a concentration higher than the concentration of said first chemical species,
wherein said at least one second chemical species is less effective than said first chemical species at weakening the substrate, and
wherein steps a) and b) can be executed in either order;
c) diffusing at least a portion of said at least one second chemical species from said second depth to the vicinity of said first depth, and
d) initiating said fracture along said first depth.

2. A fabrication method according to claim 1, wherein said second depth is greater than said first depth.

3. A fabrication method according to claim 1, wherein said second depth is less than said first depth.

4. A fabrication method according to claim 2, wherein implanting at least one second chemical species is carried out before implanting said first chemical species.

5. A fabrication method according to claim 1, wherein said diffusing at least a portion of said second chemical species further comprises applying a heat treatment.

6. A fabrication method according to according to claim 1, wherein initiating said fracture further comprises applying a heat treatment.

7. A fabrication method according to according to claim 5, wherein steps c) and d) are carried out simultaneously.

8. A fabrication method according to according to claim 5, wherein applying said heat treatment comprises carrying out said heat treatment within a thermal budget lower than that which would be necessary to initiate said fracture in the absence of steps b) and c).

9. A fabrication method according to claim 5, wherein a predetermined thermal budget is complied with, by implanting an additional amount of said at least one second chemical species.

10. A fabrication method according to claim 5, wherein applying said heat treatment comprises one or more of heating in a furnace, heating, or laser heating.

11. A fabrication method according to wherein initiating said fracture includes applying mechanical stresses.

12. A fabrication method according to claim 11, wherein applying said mechanical stresses comprises one or more of applying a jet of fluid, inserting a blade into the implanted region, applying traction, applying shear or bending stresses to the substrate, or applying acoustic waves.

13. A fabrication method according to claim 1, wherein, before or during initiating said fracture, a thickener is applied to said substrate to serve as a support for said thin layer after said fracture of said thin layer from said substrate.

14. A fabrication method according to claim 1, wherein, before or during initiating said fracture, a handle support is applied to said substrate, after which said thin layer is transferred onto a final support.

15. A fabrication method according to claim 1 wherein said first chemical species comprises 0 hydrogen.

16. A fabrication method according to claim 1, wherein said at least one chemical species comprises at least one rare gas.

17. A thin layer fabricated by a method according to claim 1.

18. A thin layer (6) according to claim 17, further comprising one of a flexible or rigid support underlying said thin layer.

19. A fabrication method according to claim 3, wherein implanting at least one second chemical species is carried out before implanting said first chemical species.

20. A fabrication method according to according to claim 6, wherein steps c) and d) are carried out simultaneously.

21. A fabrication method according to according to claim 6, wherein applying said heat treatment comprises carrying out said heat treatment within a thermal budget lower than that which would be necessary to initiate said fracture in the absence of steps b) and c).

22. A fabrication method according to according to claim 7, wherein applying said heat treatment comprises carrying out said heat treatment within a thermal budget lower than that which would be necessary to initiate said fracture in the absence of steps b) and c).
